(19) United States
(12) Patent Application Publication
(10) Pub. No.: US 2016/0240520 A1
(43) Pub. Date: Aug. 18, 2016

(54) CHIP PACKAGE AND MANUFACTURING METHOD THEREOF

(71) Applicant: XINTEC INC., Taoyuan City (TW)

(72) Inventors: Yen-Shih Ho, Kaohsiung City (TW); Shu-Ming Chang, New Taipei City (TW); Hsing-Lung Shen, Hsinchu City (TW)

(21) Appl. No.: 15/007,124

(22) Filed: Jan. 26, 2016

Related U.S. Application Data
(60) Provisional application No. 62/116,759, filed on Feb. 16, 2015.

(51) Int. Cl. H01L 25/16; H01L 21/304; H01L 21/78; H01L 21/48; H01L 23/00; H01L 23/498

(52) U.S. Cl. CPC H01L 25/16; H01L 24/05; H01L 24/16; H01L 23/49894; H01L 21/78; H01L 21/486; H01L 24/94; H01L 21/304; H01L 2224/0233; H01L 2224/024; H01L 2224/0383; H01L 2224/16225; H01L 2224/16055; H01L 2224/16057; H01L 2924/19011; H01L 2924/19042; H01L 2924/05032

(57) ABSTRACT

A chip package includes a chip, a dielectric bonding layer, a carrier, and a redistribution layer. The chip has a substrate, a conductive pad, and a protection layer. The dielectric bonding layer is located on the protection layer and between the carrier and the protection layer. The carrier, the dielectric bonding layer, and the protection layer have a communicated through hole configured to expose the conductive pad. The redistribution layer includes a connection portion and a passive component portion. The connection portion is located on the conductive pad, the sidewall of the through hole, and a surface of the carrier facing away from the dielectric bonding layer. The passive component portion is located on the surface of the carrier, and an end of the passive component portion is connected to the connection portion that is on the surface of the carrier.

### RELATED APPLICATIONS

This application claims priority to U.S. provisional Application Ser. No. 62/116,759, filed Feb. 16, 2015, which is herein incorporated by reference.

### BACKGROUND

1. Field of Invention

The present invention relates to a chip package and a manufacturing method of the chip package.

2. Description of Related Art

A typical RF (Radio Frequency) sensor includes a chip package and a passive component. For example, the passive component is an inductor. The chip package is an active component. The chip package and the inductor are both disposed on a printed circuit board, and the inductor is located outside the chip package.

In other words, after the chip package is manufactured completely, an independent inductor is required to be disposed on the printed circuit board to enable the RF sensor to work normally. As a result, the assembly time of the RF sensor is significantly increased, and the cost of the inductor is hard to be reduced. In addition, the circuit and space of the printed circuit board need to be reserved for assembling the inductor, which is an inconvenient factor for design.

### SUMMARY

An aspect of the present invention is to provide a chip package.

According to an embodiment of the present invention, a chip package includes a chip, a dielectric bonding layer, a carrier, and a redistribution layer. The chip has a substrate, a conductive pad, and a protection layer. The protection layer is located on the substrate, and the conductive pad is located in the protection layer. The dielectric bonding layer is located on the protection layer. The dielectric bonding layer is between the carrier and the protection layer. The carrier, the dielectric bonding layer, and the protection layer have a communicated through hole, such that the conductive pad is exposed through the through hole. The redistribution layer includes a connection portion and a passive component portion. The connection portion is located on the conductive pad, a sidewall of the through hole, and a surface of the carrier facing away from the dielectric bonding layer. The passive component portion is located on the surface of the carrier. An end of the passive component portion is connected to the connection portion that is on the surface of the carrier.

Another aspect of the present invention is to provide a manufacturing method of a chip package.

According to an embodiment of the present invention, a manufacturing method of a chip package includes the following steps. A dielectric bonding layer is utilized to adhere a carrier to a wafer, and the wafer has a substrate, a conductive pad, and a protection layer, and the conductive pad is located in the protection layer, and the dielectric bonding layer is between the protection layer and the carrier. A surface of the carrier facing away from the dielectric bonding layer is etched, such that the carrier, the dielectric bonding layer, and the protection layer have a communicated through hole, and the conductive pad is exposed through the through hole. A redistribution layer is formed on the conductive pad, a sidewall of the through hole, and the surface of the carrier. The redistribution layer is patterned to synchronously form a connection portion and a passive component portion, and the connection portion is located on the conductive pad, the sidewall of the through hole, and the surface of the carrier, and the passive component portion is located on the surface of the carrier, and an end of the passive component portion is connected to the connection portion that is on the surface of the carrier.

In the aforementioned embodiments of the present invention, since the redistribution layer of the chip package has the passive component portion, the chip package has a function of a passive component besides a function of an active component. For example, the passive component portion may be used as an inductor in the chip package. The carrier can support the redistribution layer. When the redistribution layer is patterned, the connection portion and the passive component portion are synchronously formed, such that the passive component portion is located on the surface of the carrier, and the time for manufacturing the passive component portion can be reduced. The chip package of the present invention may be used as an RF sensor and has a function of an inductor without needing to install a typical independent inductor. Consequently, a lot of assembly time is reduced and the cost of a typical inductor is eliminated. Moreover, a printed circuit board on which the chip package is disposed do not need reserve the circuit and space for assembling a typical inductor, thereby increasing design convenience.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of a chip package according to one embodiment of the present invention;

FIG. 2 is a schematic view of a layout of a redistribution layer of the chip package shown in FIG. 1;

FIG. 3 is a flow chart of a manufacturing method of a chip package according to one embodiment of the present invention;

FIG. 4 is a cross-sectional view of a wafer after being adhered to a carrier according to one embodiment of the present invention;

FIG. 5 is a cross-sectional view of the carrier shown in FIG. 4 after being ground;

FIG. 6 is a cross-sectional view of a through hole after being formed in the carrier, a dielectric bonding layer, and a protection layer shown in FIG. 5;

FIG. 7 is a cross-sectional view of a redistribution layer after being formed on a conductive pad, a sidewall of the through hole, and the carrier shown in FIG. 6;

FIG. 8 is a cross-sectional view of a conductive structure after being formed on the redistribution layer shown in FIG. 7;

FIG. 9 is a cross-sectional view of a substrate shown in FIG. 8 after being ground;

FIG. 10A is a cross-sectional view of a chip package according to one embodiment of the present invention;

FIG. 10B is a schematic view of a layout of a redistribution layer of the chip package shown in FIG. 10A,

FIG. 11A is a cross-sectional view of a chip package according to one embodiment of the present invention;

FIG. 11B is a schematic view of a layout of a redistribution layer of the chip package shown in FIG. 11A; and

FIG. 11C is an example of the layout of the redistribution layer shown in FIG. 11B.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

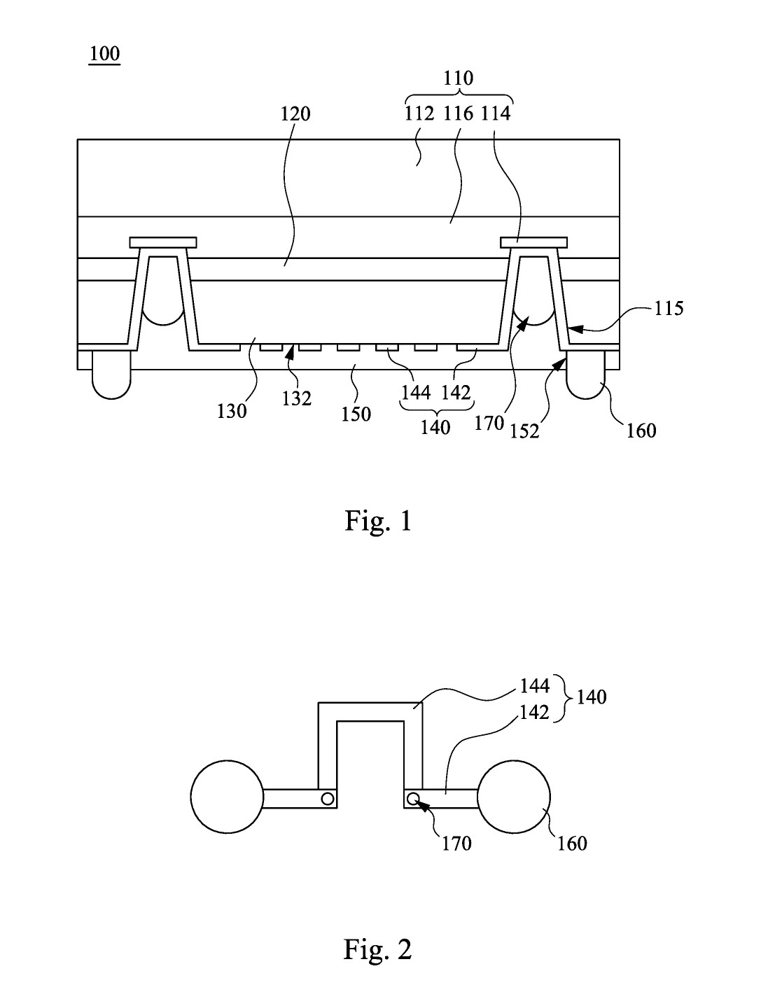

FIG. 1 is a cross-sectional view of a chip package 100 according to one embodiment of the present invention. FIG. 2 is a schematic view of a layout of a redistribution layer 140 of the chip package 100 shown in FIG. 1. As shown in FIG. 1 and FIG. 2, the chip package 100 includes a chip 110, a dielectric bonding layer 120, a carrier 130, and the redistribution layer 140. The chip 110 has a substrate 112, a conductive pad 114, and a protection layer 116. The protection layer 116 is located on the substrate 112. The conductive pad 114 is located in the protection layer 116. The dielectric bonding layer 120 is located on the protection layer 116 and is between the carrier 130 and the protection layer 116. The carrier 130, the dielectric bonding layer 120, and the protection layer 116 have a communicated through hole 115, such that the conductive pad 114 is exposed through the through hole 115. The redistribution layer 140 includes a connection portion 142 and a passive component portion 144. The connection portion 142 is located on the conductive pad 114, a sidewall of the through hole 115, and a surface 132 of the carrier 130 facing away from the dielectric bonding layer 120. The passive component portion 114 is located on the surface 132 of the carrier 130, and an end of the passive component portion 144 is connected to the connection portion 142 that is on the surface 132 of the carrier 130.

In this embodiment, the chip package 100 may be an RF sensor, but the present invention is not limited in this regard. The substrate 112 may be made of a material including silicon. The protection layer 116 may include an inter-layer dielectric (ILD), an inter-metal dielectric (IMD), and a passivation layer. The dielectric bonding layer 120 may be made of a material including polymer or oxide. The carrier 130 may be made of a material including aluminum nitride or glass that has high impedance and high dielectric constant (high-k), thereby reducing the power consumption of the chip package 100 to save power. The redistribution layer 140 may be made of a material including aluminum or copper. Physical vapor deposition (PVD) or electroplating method may be utilized to form the redistribution layer 140 to cover the conductive pad 114, the sidewall of the through hole 115, and the carrier 130. Thereafter, a patterning process may be performed on the redistribution layer 140 to synchronously form the connection portion 142 and the passive component portion 144. The patterning process may include exposure, development, and etching processes in photolithography.

Since the redistribution layer 140 of the chip package 100 has the passive component portion 144, the chip package 100 has a function of a passive component besides a function of an active component. For example, the passive component portion 144 may be used as an inductor in the chip package 100. The chip package 100 of the present invention has a function of an inductor without needing to install a typical independent inductor. Consequently, a lot of assembly time is reduced and the cost of a typical inductor is eliminated.

The carrier 130 is able to support the redistribution layer 140. When the redistribution layer 140 is patterned, the connection portion 142 and the passive component portion 144 are synchronously formed, such that the passive component portion 144 is located on the surface 132 of the carrier 130, and the time for manufacturing the passive component portion 144 can be reduced. Moreover, a printed circuit board on which the chip package is disposed do not need to reserve the circuit and space for assembling a typical inductor, thereby increasing design convenience.

In this embodiment, the shape of the passive component portion 144 is a U-shape, but the present invention is not limited in this regard. Designers may determine the layout of the redistribution layer 140 according to actual requirements, and thus the passive component portion 144 may have other shapes.

The chip package 100 may further include a passivation layer 150 and a conductive structure 160. The passivation layer 150 is located on the redistribution layer 140 and the surface 132 of the carrier 130. The passivation layer 150 has an opening 152, such that the connection portion 142 is exposed through the opening 152. The conductive structure 160 is located on the connection portion 142 that is in the opening 152 of the passivation layer 152. Therefore, the conductive structure 160 may be electrically connected to the conductive pad 114 through the connection portion 142 of the redistribution layer 140. The conductive structure 160 may be a solder ball of ball grid array (BGA) or a conductive protrusion. In addition, the chip package 100 may further selectively have a cavity 170. The cavity 170 is between the passivation layer 150 and the connection portion 142 that is in the opening 115.

Hereinafter, the manufacturing method of the chip package 100 will be described.

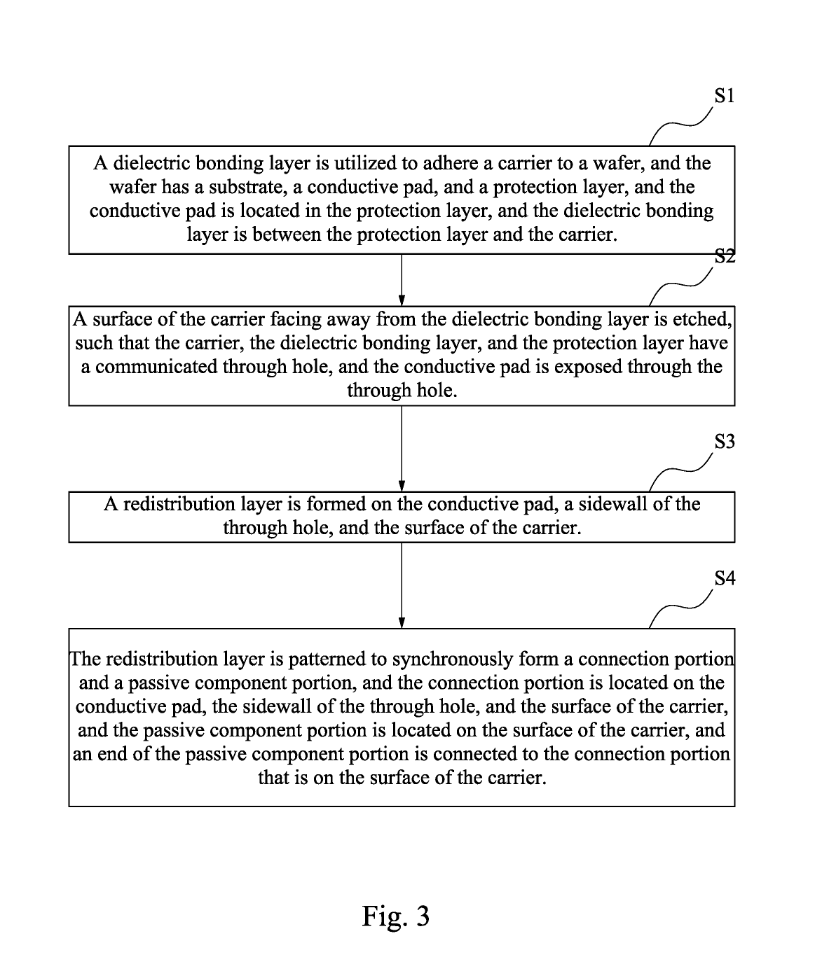

FIG. 3 is a flow chart of a manufacturing method of a chip package according to one embodiment of the present invention. The manufacturing method of the chip package includes the following steps. In step S1, a dielectric bonding layer is utilized to adhere a carrier to a wafer, and the wafer has a substrate, a conductive pad, and a protection layer, and the conductive pad is located in the protection layer, and the dielectric bonding layer is between the protection layer and the carrier. Thereafter, in step S2, a surface of the carrier facing away from the dielectric bonding layer is etched, such that the carrier, the dielectric bonding layer, and the protection layer have a communicated through hole, and the conductive pad is exposed through the through hole. Subsequently, in step S3, a redistribution layer is formed on the conductive pad, a sidewall of the through hole, and the surface of the carrier. Afterwards, in Step S4, the redistribution layer is patterned to synchronously form a connection portion and a passive component portion, and the connection portion is located on the conductive pad, the sidewall of the through hole, and the surface of the carrier, and the passive component portion is located on the surface of the carrier, and an end of the passive component portion is connected to the connection portion that is on the surface of the carrier. In the following description, the aforesaid steps will be explained.

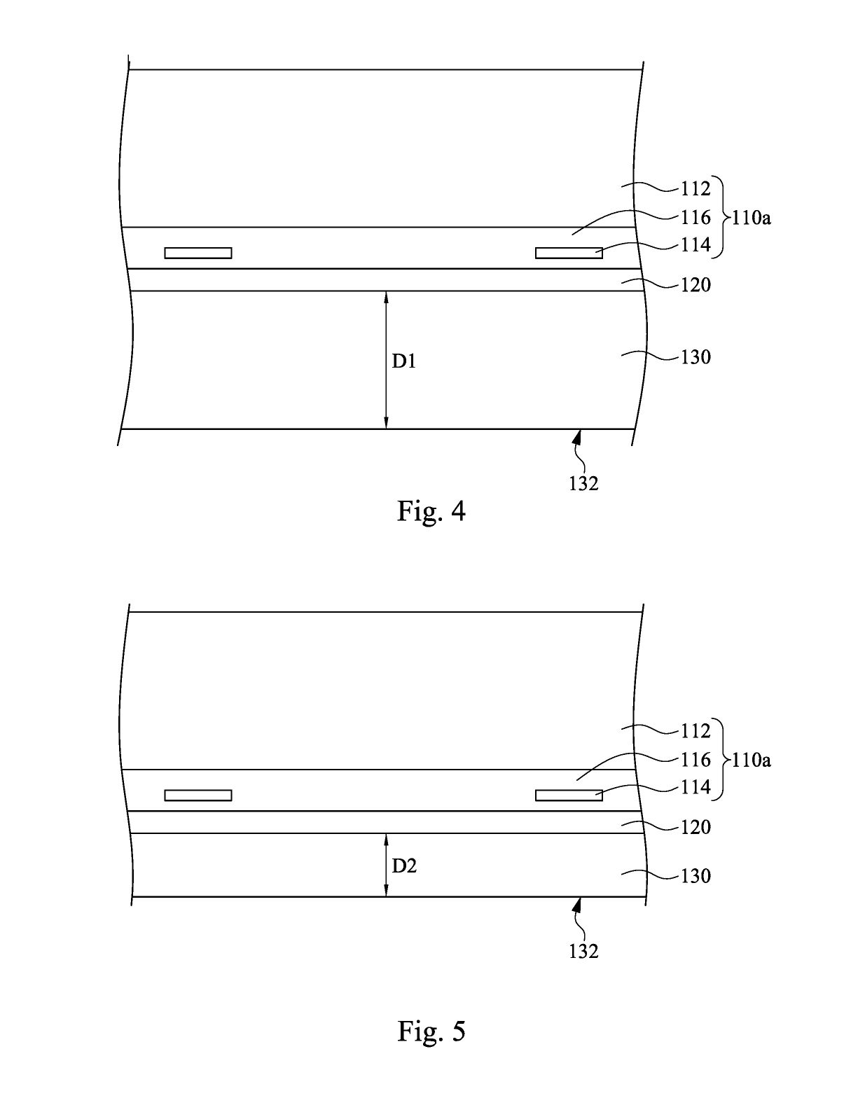

FIG. 4 is a cross-sectional view of a wafer 110a after being adhered to the carrier 130 according to one embodiment of the present invention. FIG. 5 is a cross-sectional view of the carrier 130 shown in FIG. 4 after being ground. In the following description, the wafer 110a is referred to as a semiconductor structure that is not yet divided into plural chips (e.g., the chip 110 of FIG. 1). The wafer 110a has the substrate 112, the conductive pad 114, and the protection layer 116. As shown in FIG. 4 and FIG. 5, the dielectric bonding layer 120 is utilized to adhere the carrier 130 to the wafer 110a, such that the dielectric bonding layer 120 is between the protection layer 116 and the carrier 130. The carrier 130 may be made of a material including aluminum nitride or glass, so as to provide the supporting strength to the wafer 110a. Thereafter, the surface 132 of the carrier 130 facing away from the dielectric bonding layer 120 is ground to decrease the thickness of the carrier 130. As a result, the thickness D1 of the carrier 130 is reduced to the thickness D2.

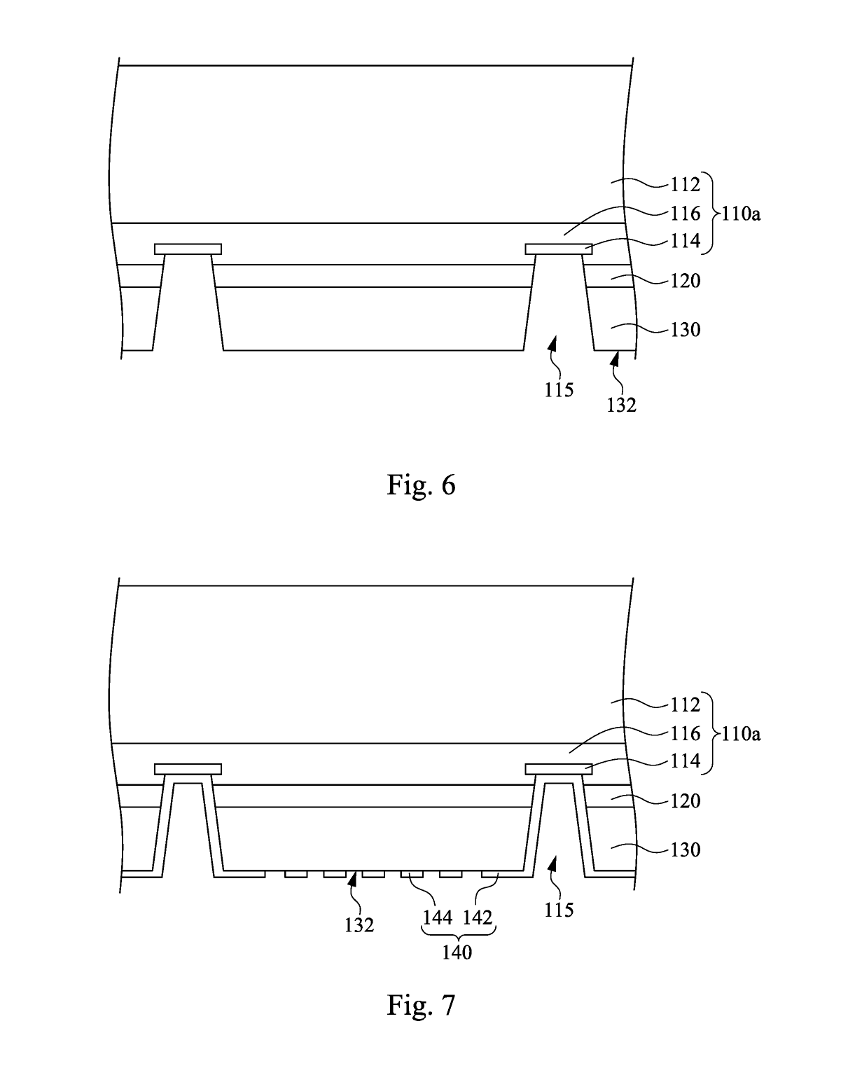

FIG. 6 is a cross-sectional view of the through hole 115 after being formed in the carrier 130, the dielectric bonding layer 120, and the protection layer 116 shown in FIG. 5. As shown in FIG. 5 and FIG. 6, after the thickness of the carrier 130 is reduced, the surface 132 of the carrier 130 may be etched, such that the carrier 130, the dielectric bonding layer 120, and the protection layer 116 have the communicated through hole 115. The through hole 115 is aligned with the conductive pad 114, so that the conductive pad 115 can be exposed through the through hole 115.

FIG. 7 is a cross-sectional view of the redistribution layer 140 after being formed on the conductive pad 114, the sidewall of the through hole 115, and the carrier 130 shown in FIG. 6. As shown in FIG. 6 and FIG. 7, after the conductive pad 114 is exposed through the through hole 115, the redistribution layer 140 is formed on the conductive pad 114, the sidewall of the through hole 115, and the surface 132 of the carrier 130. Thereafter, the redistribution layer 140 is patterned, such that the connection portion 142 and the passive component portion 144 are synchronously formed in the redistribution layer 140. The connection portion 142 is located on the conductive pad 114, the sidewall of the through hole 115, and the surface 132 of the carrier 130. The passive component portion 144 is located on the surface 132 of the carrier 130, and an end of the passive component portion 144 is connected to the connection portion 142 that is on the surface 132 of the carrier 130.

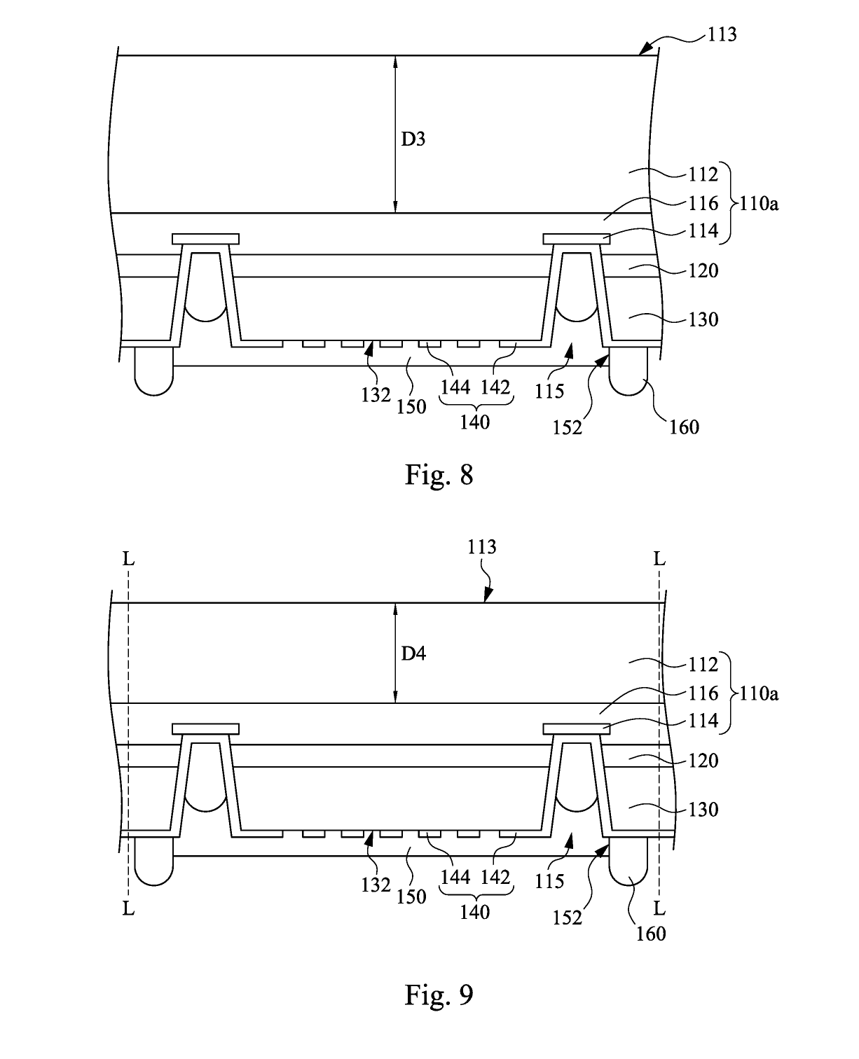

FIG. 8 is a cross-sectional view of the conductive structure 160 after being formed on the redistribution layer 140 shown in FIG. 7. As shown in FIG. 7 and FIG. 8, after the redistribution layer 140 is patterned to form the connection portion 142 and the passive component portion 144, the passivation layer 150 may be formed on the redistribution layer 140 and the surface 132 of the carrier 130. Afterwards, the passivation layer is patterned to form the opening 152, such that the connection portion 142 of the redistribution layer 140 is exposed through the opening 152. Subsequently, the conductive structure 160 is formed on the connection portion 142 that is in the opening 152 of the passivation layer 150, such that the conductive structure 160 is electrically connected to the conductive pad 114 through the connection portion 142.

FIG. 9 is a cross-sectional view of the substrate 112 shown in FIG. 8 after being ground. As shown in FIG. 8 and FIG. 9, after the conductive structure 160 is formed, a surface 113 of the substrate 112 facing away from the protection layer 116 may be ground to decrease the thickness of the substrate 112. As a result, the thickness D3 of the substrate 112 is reduced to the thickness D4. Thereafter, the wafer 110a, the dielectric bonding layer 120, the carrier 130, and the passivation layer 150 can be cut along line L-L. As a result, the chip package 100 of FIG. 1 is obtained.

It is to be noted that the connection relationships and materials of the elements described above will not be repeated in the following description, and only aspects related to other types of chip package will be described.

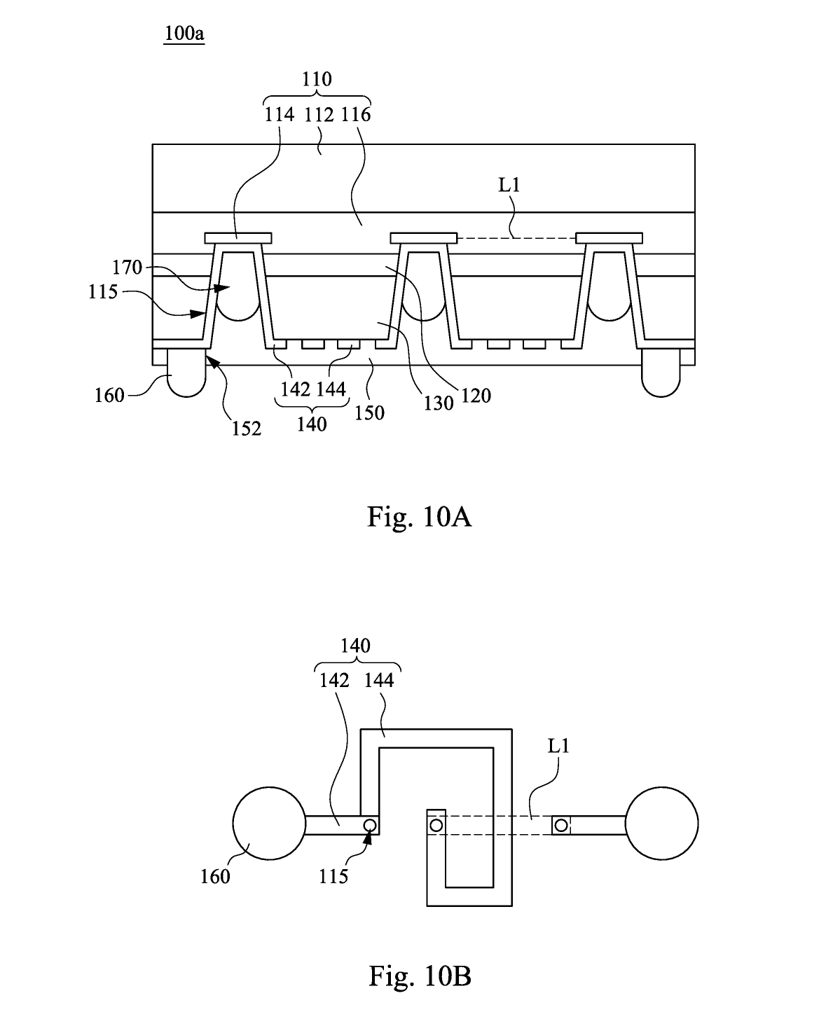

FIG. 10A is a cross-sectional view of a chip package 100a according to one embodiment of the present invention. FIG. 10B is a schematic view of the layout of the redistribution layer 140 of the chip package 100a shown in FIG. 10A. As shown in FIG. 10A and FIG. 10B, the chip package 100a includes the chip 110, the dielectric bonding layer 120, the carrier 130, and the redistribution layer 140. The redistribution layer 140 includes the connection portion 142 and the passive component portion 144. The difference between this embodiment and the embodiment shown in FIGS. 1 and 2 is that the shape of the passive component portion 144 of FIGS. 10A and 10B is a flat spiral shape. The chip 110 has a conductive line L1 that is in the protection layer 116, and the conductive line L1 is connected to the conductive pad 114 and another adjacent conductive pad 114.

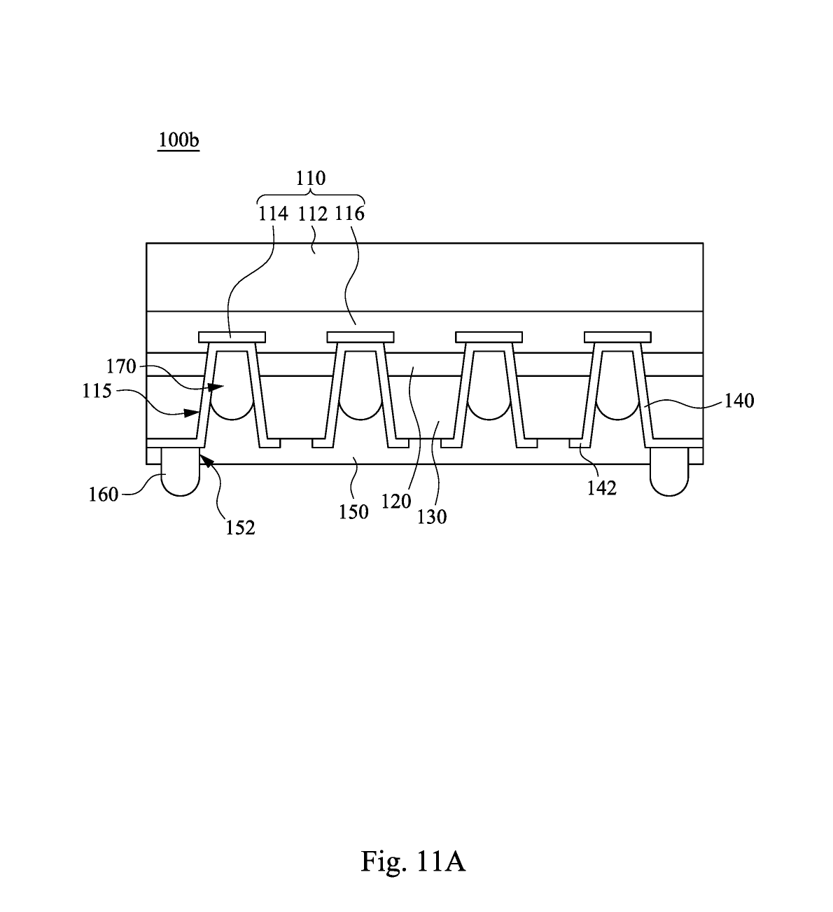

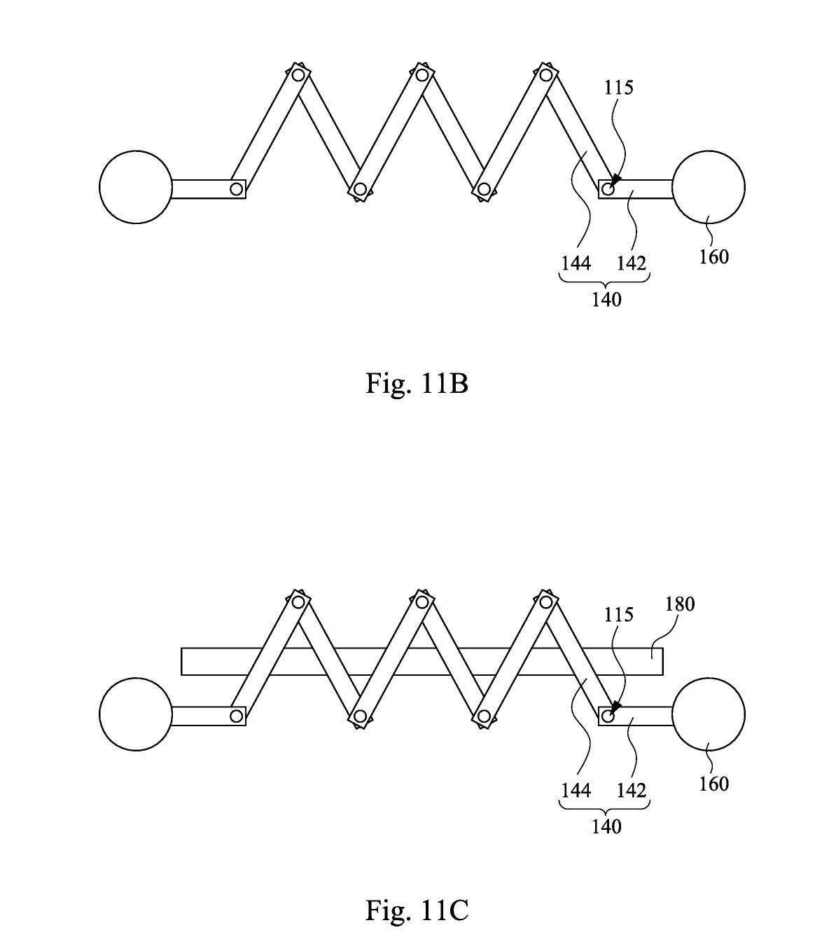

FIG. 11A is a cross-sectional view of a chip package 100b according to one embodiment of the present invention. FIG. 11B is a schematic view of the layout of the redistribution layer 140 of the chip package 100b shown in FIG. 11A. As shown in FIG. 11A and FIG. 11B, the chip package 100b includes the chip 110, the dielectric bonding layer 120, the carrier 130, and the redistribution layer 140. The redistribution layer 140 includes the connection portion 142 and the passive component portion 144. The difference between this embodiment and the embodiment shown in FIGS. 1 and 2 is that the shape of the passive component portion 144 of FIGS. 11A and 11B is a three-dimensional spiral shape. In other words, positions of the passive component portion 144 are not at the same horizontal level.

FIG. 11C is an example of the layout of the redistribution layer 114 shown in FIG. 11B. As shown in FIG. 11A and FIG. 11C, the chip package 100b includes the chip 110, the dielectric bonding layer 120, the carrier 130, and the redistribution layer 140. The redistribution layer 140 includes the connection portion 142 and the passive component portion 144. The difference between this embodiment and the embodiment shown in FIG. 11B is that the chip 110 further includes a magnetic element 180. The magnetic element 180 is surrounded by the passive component portion 140 of FIG. 11C. In this embodiment, the magnetic element 180 can increase the inductance value of the chip package 100b.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A chip package, comprising:
a chip having a substrate, a conductive pad, and a protection layer, wherein the protection layer is located on the substrate, and the conductive pad is located in the protection layer;
a dielectric bonding layer located on the protection layer;
a carrier, wherein the dielectric bonding layer is between the carrier and the protection layer, and the carrier, the dielectric bonding layer, and the protection layer have a communicated through hole, such that the conductive pad is exposed through the through hole; and
a redistribution layer, comprising:
a connection portion located on the conductive pad, a sidewall of the through hole, and a surface of the carrier facing away from the dielectric bonding layer; and
a passive component portion located on the surface of the carrier, wherein an end of the passive component portion is connected to the connection portion that is on the surface of the carrier.

2. The chip package of claim 1, wherein a shape of the passive component portion comprises a U-shape, a flat spiral shape, and a three-dimensional spiral shape.

3. The chip package of claim 1, further comprising:
a passivation layer located on the redistribution layer and the surface of the carrier.

4. The chip package of claim 3, wherein the passivation layer has an opening configured to expose the connection portion, and the chip package further comprises:
a conductive structure located on the connection portion that is in the opening of the passivation layer, wherein the conductive structure is electrically connected to the conductive pad.

5. The chip package of claim 4, wherein the conductive structure is a solder ball or a conductive protrusion.

6. The chip package of claim 3, having a cavity, wherein the cavity is between the passivation layer and the connection portion that is in the through hole.

7. The chip package of claim 1, wherein the chip further comprises:
a magnetic element surrounded by the passive component portion.

8. The chip package of claim 1, wherein the carrier is made of a material comprising aluminum nitride or glass.

9. The chip package of claim 1, wherein the dielectric bonding layer is made of a material comprising polymer or oxide.

10. The chip package of claim 1, wherein the chip has a conductive line that is in the protection layer, and the conductive line is connected to the conductive pad and another adjacent conductive pad.

11. A manufacturing method of a chip package, the manufacturing method comprising:
utilizing a dielectric bonding layer to adhere a carrier to a wafer, wherein the wafer has a substrate, a conductive pad, and a protection layer, and the conductive pad is located in the protection layer, and the dielectric bonding layer is between the protection layer and the carrier;
etching a surface of the carrier facing away from the dielectric bonding layer, such that the carrier, the dielectric bonding layer, and the protection layer have a communicated through hole, and the conductive pad is exposed through the through hole;
forming a redistribution layer on the conductive pad, a sidewall of the through hole, and the surface of the carrier; and
patterning the redistribution layer to synchronously form a connection portion and a passive component portion, wherein the connection portion is located on the conductive pad, the sidewall of the through hole, and the surface of the carrier, and the passive component portion is located on the surface of the carrier, and an end of the passive component portion is connected to the connection portion that is on the surface of the carrier.

12. The manufacturing method of claim 11, further comprising:
grinding the surface of the carrier for decreasing a thickness of the carrier.

13. The manufacturing method of claim 11, further comprising:
forming a passivation layer on the redistribution layer and the surface of the carrier; and
patterning the passivation layer to form an opening, such that the connection portion is exposed through the opening.

14. The manufacturing method of claim 13, further comprising:
forming a conductive structure on the connection portion that is in the opening of the passivation layer, such that the conductive structure is electrically connected to the conductive pad.

15. The manufacturing method of claim 14, further comprising:
cutting the wafer, the dielectric bonding layer, the carrier, and the passivation layer.

16. The manufacturing method of claim 11, further comprising:
grinding a surface of the substrate facing away from the protection layer for decreasing a thickness of the substrate.
